(19) United States
(12) Patent Application Publication
(10) Pub. No.: US 2022/0285134 A1
(43) Pub. Date: Sep. 8, 2022

(54) NEAR NETSHAPE ADDITIVE MANUFACTURING USING LOW TEMPERATURE PLASMA JETS

(71) Applicants: LAM RESEARCH CORPORATION, Fremont, CA (US); SILFEX, INC., Eaton, OH (US)

(72) Inventors: Abhinav Shekhar RAO, Cambridge, MA (US); Seyedalireza TORBATISARRAF, San Jose, CA (US); Jerome HUBACEK, Fremont, CA (US); Jihong CHEN, Cincinnati, OH (US); Yi SONG, Cincinnati, OH (US)

(21) Appl. No.: 17/637,140

(22) PCT Filed: Aug. 19, 2020
(86) PCT No.: PCT/US2020/046997

§ 371 Date: Feb. 22, 2022

Related U.S. Application Data
(60) Provisional application No. 62/890,779, filed on Aug. 23, 2019.

(51) Int. Cl. H01J 37/32; C23C 4/134; C23C 4/067; B33Y 70/10

(52) U.S. Cl. CPC H01J 37/32449; C23C 4/134; C23C 4/067; H01J 37/32357; B33Y 70/10

(57) ABSTRACT

A system comprises an apparatus having a nozzle. An element is arranged around the apparatus. A feeder is configured to supply a powder of a material into the apparatus. A gas source is configured to supply a precursor gas into the apparatus and to supply an inert gas to circulate through a space between the element and the apparatus and to exit around the nozzle. A plasma generator is arranged in the apparatus and is configured to ionize the precursor gas and atomize the powder and to eject through the nozzle a jet of particles composed of the atomized powder and the ionized precursor gas onto a substrate arranged adjacent to the nozzle.

### CROSS-REFERENCE TO RELATED APPLICATIONS

This application claims the benefit of U.S. Provisional Application No. 62/890,779, filed on Aug. 23, 2019. The entire disclosure of the application referenced above is incorporated herein by reference.

### FIELD

The present disclosure relates generally to manufacturing silicon components and more particularly to additive manufacturing of near net shape silicon components using low temperature plasma jets.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform treatments such as etching of substrates such as semiconductor wafers. During processing, a substrate is arranged on a substrate support such as a pedestal, an electrostatic chuck (ESC), and so on in a processing chamber of the substrate processing system. During etching, gas mixtures including etch gases are introduced into the processing chamber, and plasma is struck to activate chemical reactions. A computer-controlled robot typically transfers substrates from one processing chamber to another in a sequence in which the substrates are to be processed.

### SUMMARY

A system comprises an apparatus having a nozzle. An element is arranged around the apparatus. A feeder is configured to supply a powder of a material into the apparatus. A gas source is configured to supply a precursor gas into the apparatus and to supply an inert gas to circulate through a space between the element and the apparatus and to exit around the nozzle. A plasma generator is arranged in the apparatus and is configured to ionize the precursor gas and atomize the powder and to eject through the nozzle a jet of particles composed of the atomized powder and the ionized precursor gas onto a substrate arranged adjacent to the nozzle.

In another feature, the material is selected from a group consisting of silicon, ceramics, and refractory metals.

In another feature, the system further comprises a controller configured to maintain a temperature of the substrate and materials deposited on the substrate to less than a ductile to brittle transition temperature of the material.

In another feature, the apparatus deposits one or more layers of the particles onto the substrate.

In another feature, the system further comprises a controller configured to alter one or more of electrical, thermal, and chemical properties at a plurality of locations in a single layer or across a plurality of layers of the particles deposited onto the substrate by controlling one or more of the feeder, the gas source, and the plasma generator.

In another feature, the system further comprises a controller configured to select a dopant to add to the material into the apparatus during deposition of one or more layers of the particles onto the substrate.

In another feature, the system further comprises a controller configured to select, during deposition of one or more layers of the particles onto the substrate, at least one of a type of the material and a feed rate of the selected material supplied by the feeder.

In another feature, the system further comprises a controller configured to select, during deposition of one or more layers of the particles onto the substrate, at least one of a type of the precursor gas and a flow rate of the selected precursor gas supplied by the gas source.

In another feature, the system further comprises a controller configured to select power supplied to the plasma generator during deposition of one or more layers of the particles onto the substrate.

In other features, the system further comprises a gantry system configured to move at least one of the apparatus and the substrate and a controller configured to move the gantry system during deposition of one or more layers of the particles onto the substrate.

In other features, the apparatus has a circular shape and a conical end forming the nozzle and wherein the element is arranged concentrically around the apparatus.

In still other features, a method comprises supplying a powder of a material into an apparatus having a nozzle, supplying a precursor gas into the apparatus, and generating plasma in the apparatus to ionize the precursor gas and atomize the powder. The method further comprises circulating an inert gas around the apparatus to minimize interaction between the plasma and ambient atmosphere and to focus a plasma jet composed of materials including the atomized powder and the ionized precursor gas onto a substrate arranged adjacent to the nozzle of the apparatus. The method further comprises controlling a temperature of the substrate and the materials deposited on the substrate to less than a ductile to brittle transition temperature of the material.

In another feature, the method further comprises selecting the material from a group consisting of silicon, ceramic, and refractory metal.

In another feature, the method further comprises depositing one or more layers of the materials onto the substrate.

In another feature, the method further comprises controlling one or more of electrical, thermal, and chemical properties at a plurality of locations in a single layer or across a plurality of layers of the materials deposited onto the substrate by controlling one or more of a type of the material, a rate of supplying the powder, a type of the precursor gas, and a rate of supplying the precursor gas.

In another feature, the method further comprises controlling supply of a dopant into the apparatus during deposition of one or more layers of the materials onto the substrate.

In another feature, the method further comprises, during deposition of one or more layers of the materials onto the substrate, at least one of selecting a type of the material and controlling a feed rate of the selected material.

In another feature, the method further comprises, during deposition of one or more layers of the materials onto the substrate, at least one of selecting a type of the precursor gas and controlling a flow rate of the selected precursor gas.

In another feature, the method further comprises controlling power supplied for generating the plasma during deposition of one or more layers of the materials onto the substrate.

In another feature, the method further comprises moving at least one of the apparatus and the substrate during deposition of one or more layers of the materials onto the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a processing chamber;

FIG. 2A shows a schematic of a system to print and repair components of the substrate processing system according to the present disclosure;

FIGS. 2B and 2C show examples of plasma generators used in the system of FIG. 2A; and

FIG. 3 shows a flowchart of a method for printing and repairing components of the substrate processing system according to the present disclosure.

In the drawings, reference numbers may be reused to identify similar and/or identical elements.

### DETAILED DESCRIPTION

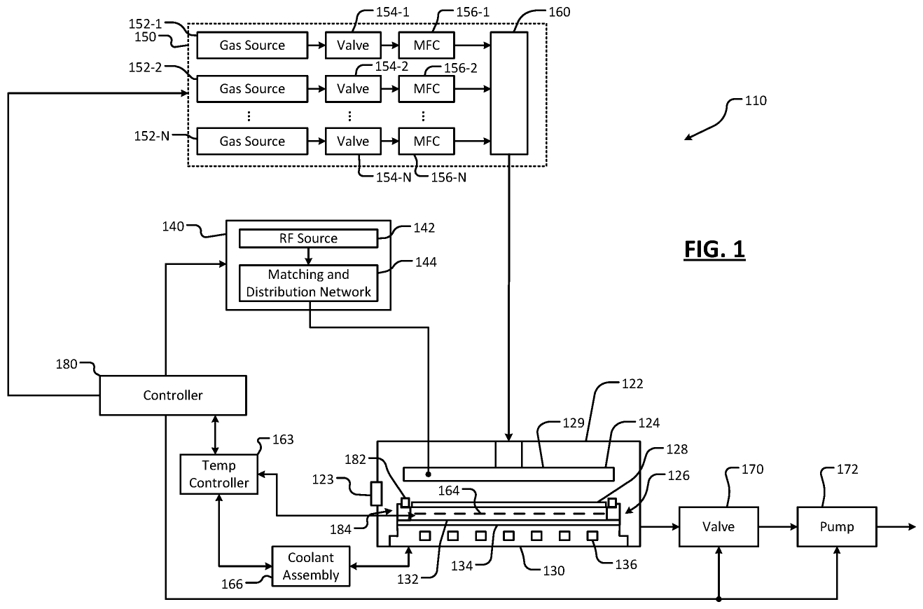

Various components used in substrate processing systems and processing chambers are manufactured with high precision. Some of these components are made of metals while others are made of materials such as silicon and ceramics. An example of a substrate processing system and a processing chamber is shown and described below with reference to FIG. 1 to provide examples of these components and the harsh electrical, chemical, and thermal environments in which these components operate.

Current methods for additive manufacturing of ceramics include selective laser melting, polymer binder jetting, and stereolithography. In these methods, the high temperature required to melt silicon, which has a melting point of 1414 degrees Celsius, results in significant residual thermal stresses. Binder jetting and stereolithography use a polymer to bind the silicon/ceramic powder to form a component, which then requires significant post-processing including chemical binder removal and sintering. Another downside of these methods is that the manufactured component is porous and therefore not fully dense. Furthermore, the materials and processes currently used and the components manufactured using them have not been qualified or certified for use with plasma and the chemicals used in the substrate processing systems and the processing chambers.

Further, since some of these components also wear due to exposure to the harsh environment, some of the worn components can be repaired using additive manufacturing. A significant amount of material and time can be saved if some of the worn components can be refurbished and/or repaired in a manner that meets their performance requirements or specifications such as conductance. Presently, worn components are scrapped or replaced when only a small fraction of material is eroded, which results in significant waste.

Briefly, the present disclosure proposes a low temperature plasma jet method for near net-shape additive manufacturing of silicon and ceramic components. Silicon or ceramic powder are injected into a plasma spray and atomized there. The jet is positioned numerically in two dimensions to print a specific pattern on a substrate. The film is then deposited layer-by-layer on the substrate to build up a three dimensional component.

The proposed system comprises a low temperature atmospheric plasma jet mounted on a three axis gantry system such that material can be deposited at pre-programmed locations in three dimensions and the motion and deposition process can be numerically controlled. A powder feedstock is injected into the plasma jet using a gas (or liquid) stream. This powder may include silicon, an oxide of silicon, or a ceramic material. The ceramic material includes an inorganic, non-metallic, often crystalline oxide, nitride, or carbide material. The powder may be in the form of nanoparticles or micro-particles depending on the application.

Plasma (e.g., RF plasma) is ignited to ionize the gases and atomize the powder. A sheath gas is added around a jet of plasma to maintain the plasma conditions and to focus the plasma jet. The atomized particles exit the plasma jet and are deposited as a film onto a substrate or a build platform. The gas composition is determined based on the plasma chemistry required to impart specific dopants or properties to the component. The composition may be altered across different areas of the component when gradients in properties are desired. The composition may be altered in different areas in a single layer as well as across different layers.

Using a numerically controlled motion system, the plasma jet (or the substrate or both) can be moved to deposit specific patterns in 2D on the substrate, which can then be built up layer-by-layer to form a 3D component. In addition, the film may be deposited in areas where existing components have been eroded, which can restore their mechanical, electrical, thermal, and chemical properties.

Accordingly, the proposed process can be used to add material onto an existing component or to print new components. The waste of high value materials can be minimized using near net shape and additive manufacturing, and new designs and materials may be implemented. For example, the process can be used to repair eroded components and to print components such as electrostatic chucks, showerheads, temperature controlled windows, gas injectors, edge rings, and so on. These and other features of the proposed process are explained below in detail.

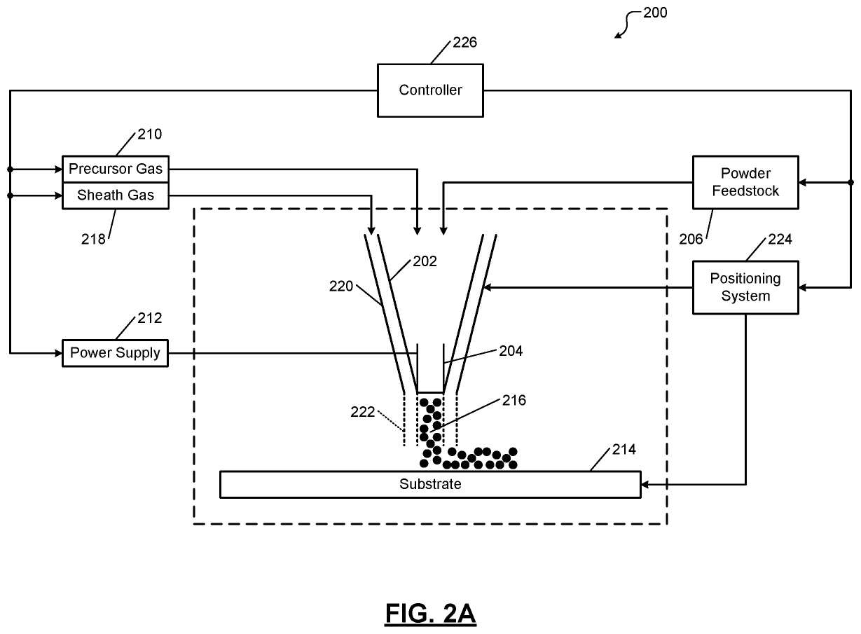

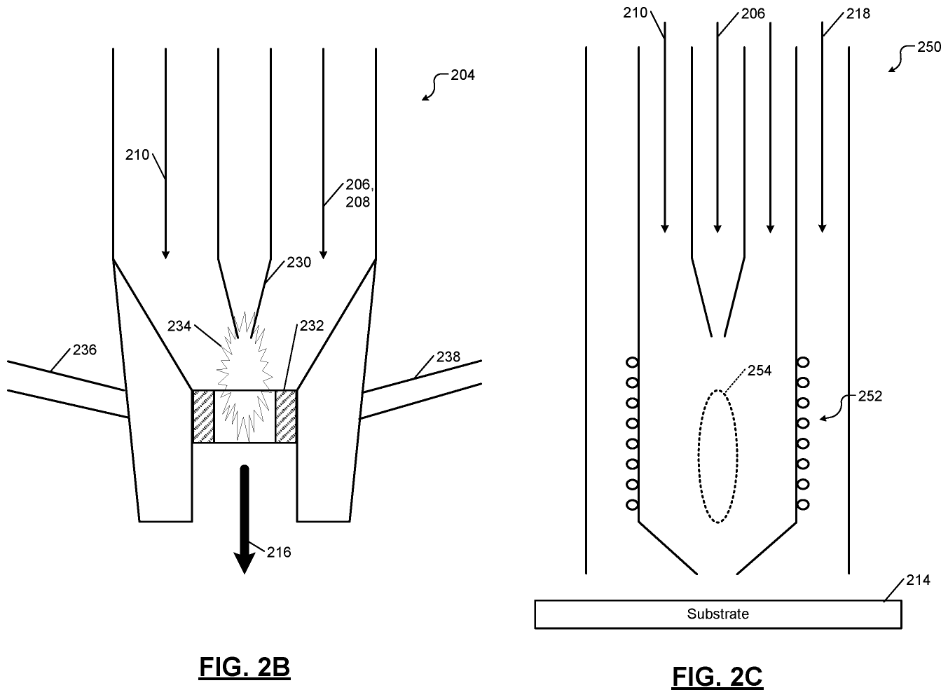

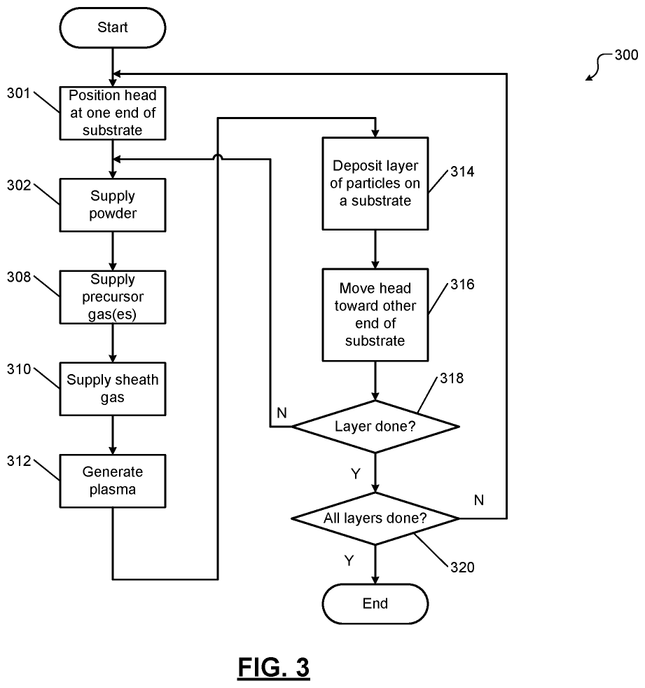

The present disclosure is organized as follows. Initially, an example of a substrate processing system including a processing chamber is shown and described with reference to FIG. 1. An example of a system to print and repair components according to the present disclosure is shown and described with references to FIGS. 2A, 2B and 2C. An example of a process to print and repair components according to the present disclosure is shown and described with references to FIG. 3.

Throughout the present disclosure, while examples of the system and the method are shown and described using silicon powder, the teachings of the present disclosure are not limited to silicon components. Rather, the teachings apply equally to other materials such as but not limited to ceramics, alumina, refractory metals, and Intermetallics.

Referring now to FIG. 1, an example of a substrate processing system 110 according to the present disclosure is shown. The substrate processing system 110 may be used to perform etching using capacitively coupled plasma (CCP). The substrate processing system 110 includes a processing chamber 122 that encloses other components of the substrate processing system 110 and contains RF plasma (if used).

When the plasma processing chamber 122 is arranged in a tool, the plasma processing chamber may include a substrate port that can be opened to a vacuum transfer module without breaking vacuum. Generally, the substrate port has a horizontal opening dimension that is slightly greater than a diameter of the substrate to be processed and a vertical opening dimension that is significantly less than the horizontal opening dimension. Generally the vertical opening dimension is wide enough to allow a robot end effector to place the substrate on lift pins of the substrate support.

The substrate processing system 110 includes an upper electrode 124 and a substrate support 126 such as an electrostatic chuck (ESC). During operation, a substrate 128 is arranged on the substrate support 126. For example only, the upper electrode 124 may include a gas distribution device 129 such as a showerhead that introduces and distributes process gases. The gas distribution device 129 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which precursor, reactants, etch gases, inert gases, carrier gases, other process gases or purge gas flows. Alternately, the upper electrode 124 may include a conducting plate and the process gases may be introduced in another manner.

The substrate support 126 includes a baseplate 130 that acts as a lower electrode. The baseplate 130 supports a heating plate 132, which may correspond to a ceramic multi-zone heating plate. A bonding layer 134 may be arranged between the heating plate 132 and the baseplate 130. In some examples, the bonding layer 134 also provides thermal resistance. The baseplate 130 may include one or more channels 136 for flowing coolant through the baseplate 130.

An RF generating system 140 generates and outputs an RF voltage to one of the upper electrode 124 and the lower electrode (e.g., the baseplate 130 of the substrate support 126). The other one of the upper electrode 124 and the baseplate 130 may be DC grounded, AC grounded or floating. For example only, the RF generating system 140 may include an RF source 142 that generates RF plasma power that is fed by a matching and distribution network 144 to the upper electrode 124 or the baseplate 130. In other examples, the plasma may be generated inductively or remotely.

A gas delivery system 150 includes one or more gas sources 152-1, 152-2, . . . , and 152-N (collectively gas sources 152), where N is an integer greater than zero. The gas sources 152 are connected by valves 154-1, 154-2, . . . , and 154-N (collectively valves 154) and MFCs 156-1, 156-2, . . . , and 156-N (collectively MFCs 156) to a manifold 160. Secondary valves may be used between the MFCs 156 and the manifold 160. In some examples, secondary valves (not shown) are arranged between the MFCs 156 and the manifold 160. While a single gas delivery system 150 is shown, two or more gas delivery systems can be used.

A temperature controller 163 may be connected to a plurality of thermal control elements (TCEs) 164 arranged in the heating plate 132. The temperature controller 163 may be used to control the plurality of TCEs 164 to control a temperature of the substrate support 126 and the substrate 128. The temperature controller 163 may communicate with a coolant assembly 166 to control coolant flow through the channels 136. For example, the coolant assembly 166 may include a coolant pump, a reservoir and/or one or more temperature sensors. The temperature controller 163 operates the coolant assembly 166 to selectively flow the coolant through the channels 136 to cool the substrate support 126.

A valve 170 and pump 172 may be used to evacuate reactants from the processing chamber 122. A system controller 180 may be used to control components of the substrate processing system 110. An edge ring system 182 including one or more edge rings may be arranged radially outside of the substrate 128 during plasma processing. An edge ring height adjustment system 184 includes one or more lift pins (shown below) that may be used to adjust a height of one or more of the edge rings of the edge ring system 182 relative to the substrate 128. In some examples, one or more of the edge rings of the edge ring system 182 can also be raised by the lift pins, removed by a robot end effector and replaced with another edge ring without breaking vacuum.

FIGS. 2A-2C show an example of a system 200 to print and repair components according to the present disclosure. In FIG. 2A, the system 200 comprises a cone shaped apparatus 202 including a plasma generator 204 near the apex of the cone. Examples of the plasma generator 204 are shown in FIGS. 2B and 2C. The cone shaped apparatus 202 including the plasma generator 204 may also be referred to as a head.

Initially, the system 200 is briefly described below with reference to FIG. 2A, where all elements of the system 200 are briefly introduced. This is followed a description of the plasma generator 204 with reference to FIGS. 2B and 2C. Subsequently, the system 200 is described in detail, where further details of operation of the elements of the system 200 are explained.

Briefly, in FIG. 2A, a feedstock 206 supplies silicon powder (or other suitable material such as ceramics, alumina, or a refractory metal) to the cone shaped apparatus 202. Optionally, depending on the application, a dopant can be added to the silicon powder in the cone shaped apparatus 202. One or more precursor gases 210 (or a liquid) are supplied to the cone shaped apparatus 202. The dopant is typically in the form of one or more precursor gases. Non-limiting examples of precursor gases include silane, hexamethyldisiloxane, silicon tetrachloride, and methane. In addition, a wide variety of gases (or liquids) containing carbon or metals may be used. A power supply 212 supplies power (e.g., RF power) to the plasma generator 204. The plasma generator 204 ignites the precursor gas to form plasma. The plasma atomizes the powder and partially ionizes the precursor gas(es). A plasma jet 216 exits the apex of the cone shaped apparatus 202 and deposits the particles on a substrate 214.

A sheath gas 218 (e.g., an inert gas such as nitrogen or argon) is circulated concentrically around the cone shaped apparatus 202 through a hollow space between the cone shaped apparatus 202 and a second cone shaped element 220 arranged around the cone shaped apparatus 202. The sheath gas 218 surrounds the plasma jet 216 as the plasma jet 216 exits the apex of the cone shaped apparatus 202 as shown at 222. The sheath gas 218 maintains the plasma condition of the plasma jet 216, minimizes the interaction of the plasma jet 216 with ambient atmosphere, and focuses the plasma jet 216 onto the substrate 214 as shown at 222.

Note that the cone shaped apparatus 202 and the second cone shaped element 220 arranged around the cone shaped apparatus 202 need not be cone shaped throughout. In some implementations, a top portion of the cone shaped apparatus 202 and the second cone shaped element 220 may be cylindrical, and only the bottom portion may be conical as shown. In general, elements 202 and 222 may include an apparatus with a circular shape and a conical end having a nozzle. Regardless of the implementation used, the apex or tip of the bottom of the conical portion is in the form of a nozzle that ejects the plasma jet 216 onto the substrate 214.

A positioning system (e.g., a three axis gantry system) 224 moves the substrate 214 or the rest of the elements of the system 200 including the cone shaped apparatus 202 or both. In some cases, the relative positioning of the cone-shaped apparatus 202 and the substrate 214 may be performed using a five-axis robotic arm. A controller 226 controls all elements of the system 200 including the movement of the cone shaped apparatus 202 and the substrate 214, type and feed rate of the feedstock 206, type and amount of dopant added, type and flow rate of the precursor gas 210, type and flow of the sheath gas 218, and the power supplied to the plasma generator 204.

FIG. 2B shows an example of the plasma generator 204. For example, the plasma generator 204 comprises a cathode 230 and an anode 232, which is in the form of a ring, and to which the power supply 212 supplied power to generate plasma 234. A coolant such as water is supplied to the plasma generator through an inlet 236. The coolant exits the plasma generator 204 through an outlet 238. Any other type of plasma generator may be used instead.

For example, FIG. 2C shows a plasma generator 250 that uses an inductively coupled plasma to atomize the powder 206 and to partially ionize the precursor gases 210. Power is supplied to an induction coil 252 to generate plasma 254.

The system 200 is now described in further detail. In components manufactured using conventional high temperature laser melting systems, a large thermal gradient usually exists after melting, which can cause cracking of a component, which in turn can result in poor print quality and lack of mechanical integrity within the component. In conventional thermal spray type systems, the rate of deposition is very slow.

In contrast, the system 200 combines the powder feed with the plasma such that a film of material can be deposited on the substrate 214 in any specified pattern at a faster rate and at a relatively low temperature compared to conventional sintering and melting processes. Further, the film deposition on the substrate 214 can be performed in the presence of air and without using any controlled environment such as a vacuum chamber or a chamber filled with inert gas. Accordingly, the system 200 can be called an atmospheric plasma jet system. However, in some cases, the system 200 may be enclosed in a vacuum or inert gas chamber, as dictated by reactant chemistry and safety requirements.

In the system 200, silicon powder is injected from the feedstock 206 into the plasma jet using a stream of a precursor gas(es) 210. The powder atomization is created in the plasma discharge region either between cathode and anode or inside an induction zone. Atomization of the powder is performed to prevent porosity and to achieve optimal grain structure in the component. The precursor gas 210 is selected based on the type of film to be deposited on a substrate.

The precursor gas 210 is ignited to form plasma, which interacts and transports the atomized feed particles to the substrate 214. A film of atoms from the powder 206 and the precursor gases 210 are deposited on the substrate 214. The film can be deposited on the substrate 214 at a faster rate and at a lower temperature than the conventional thermal spray type deposition systems.

Further, any desired doping and chemical composition can be imparted to the component by tuning the plasma composition (e.g., by changing the precursor gas 210). Thus, chemistry of deposition at specific locations in a layer or across layers on the substrate 214 can be controlled on the fly during deposition. For example, a first layer may be composed of an electrically conducting material while a second layer adjacent to the first layer may be composed of a dielectric material. Further, specific electrical (e.g., conductivity), thermal (e.g., coefficient of thermal expansion or CTE), and chemical properties can be controlled in a layer or across layers on the substrate 214 depending on the type of material injected from the feedstock 206 and/or dopant used and depending on the nature of plasma used.

A sheath of an inert gas such as nitrogen or argon is circulated concentrically around the head (i.e., around the cone shaped apparatus 202) to protect the reacting materials within the head. Specifically, the sheath gas 218 is used to minimize the plasma interacting with ambient atmosphere and to focus the plasma jet 216 onto the substrate 214.

The numerically controlled positioning system 224 is used to build a component by depositing one layer of the film on top of another on the substrate 214 by moving the head that ejects the plasma jet 216 while holding the substrate 214 stationary, by moving the substrate 214 while holding the head stationary, or by moving both. For example, the decision of whether to move the head or the substrate 214 can be inertia dependent. For example, if a small, light-weight component is being manufactured or repaired, it may be easier to move the substrate 214 since comparatively the head, along with powder feed, gas supply assemblies, and power supply, may be more complex and difficult to move than the substrate 214. Conversely, if a large or heavy component is being manufactured or repaired, it may be easier to move the head instead of moving the substrate 214. A further consideration in making the decision may be accuracy in the manufacture or repair process. For example, in some instances, moving the substrate 214 may provide the accuracy while in others moving the head instead may provide the accuracy.

The ductile to brittle transition (DBTT) point of silicon is about 700-900 degrees Celsius. Silicon is ductile at temperatures greater than the DBTT point and brittle at temperatures below the DBTT point. Accordingly, printing silicon at higher than the DBTT temperature is challenging without proper annealing and cool-down control. However, using plasma allows the printing temperature to be kept below the DBTT point and minimize the occurrence of fracturing. That is, the temperature of the plasma jet 216 and the temperature of the material being deposited on the substrate 214 is kept below the DBTT point or temperature of the material. As a result, the thermal gradient across the component being printed is lower than in the conventional 3D printing methods. For example, the controller 226 controls the temperature of the material being deposited on the substrate 214 (e.g., by controlling the power supplied to the plasma generator 204) to less than the DBTT point or temperature of the material. Thus, components of silicon (and other materials such as ceramics etc. mentioned above) can be printed at temperatures below the DBTT point of silicon (i.e., at temperatures less than about 700-900 degrees Celsius) without cracking problems.

The method of the present disclosure is not limited to printing components with silicon, alumina, and ceramic materials. The method can be used to print components with refractory metals like tungsten, which are a class of metals that are extraordinarily resistant to heat and wear. For all these materials, the printing can be performed at temperatures significantly lower than the melting temperatures of the respective materials.

FIG. 3 shows a method 300 for printing and repairing components according to the present disclosure. The method 300 is executed by the controller 226. At 301, the method 300 positions a conical apparatus comprising a plasma generator as described above with reference to FIGS. 2A-2C (hereinafter a head) at a desired starting position on a substrate on which a component is to be built or repaired.

At 302, the method 300 supplies powder of the material such as silicon, ceramic, a refractory metal, and so on to the head. At 308, the method 300 supplies one or more precursor gases to the head. The method 300 selects the one or more precursor gases depending on the component being built or repaired. At 310, the method 300 supplies a sheath gas to flow concentrically around the head. At 312, the method 300 generates plasma by igniting the one or more precursor gases. One or more dopants (contained in the precursor compound) can be added to the plasma depending on the component being built or repaired. The sheath gas minimizes the interaction of the plasma with the ambient atmosphere and focuses a plasma jet for deposition on the substrate.

At 314, the method 300 deposits a layer of the atomized particles bound by the ions on the substrate. At 316, the method 300 controls a gantry system and moves the head toward the other end of the substrate while holding the substrate stationary. In some implementations, the method 300 controls the gantry system and moves the substrate while holding the head stationary. In some other implementations, the method 300 controls the gantry system and moves both the head and the substrate.

At 318, the method 300 determines whether the layer has been deposited. If the layer has not yet been deposited, the method 300 proceeds to 302. While moving from 302 through 316, the method 300 is able to change the composition of the plasma jet (e.g.; by selecting a different precursor gas or gases, or both). Accordingly, the method 300 can alter one or more of electrical, thermal, chemical properties at one or more locations in the layer.

After the layer is deposited, the method 300 determines whether all the layers have been deposited. If all the layers have not yet been deposited, the method 300 proceeds to 301. The method 300 ends if all the layers have been deposited.

The systems and methods described above can be used to repair or print various components of substrate processing systems and processing chambers. Non-limiting examples include the following. For example, showerheads with extremely large number of fine holes can be printed using silicon or alumina, which is nearly impossible using traditional subtractive machining methods. Further, unlike traditional methods that can drill only straight holes, curved holes can be printed using the system and method of the present disclosure, which can prevent plasma formation on the backside of the showerheads. Plenums used to distribute gases to the showerheads can be printed with the showerhead, which eliminates issues associated with bonding the plenums to the showerheads.

The systems and methods can also be used to print and repair edge rings, gas injectors, and features of an ESC such as internal geometry for multizone heaters, lifter pins, and probes for measuring cooling, voltage, and temperature, and so on. The systems and methods can also be used to print and repair implants for the human body and other applications such as components for aerospace vehicles and nuclear reactors using suitable materials.

Below are some examples of dimensions of the apparatus and flow rates of the powder and the various gases. For example, the cross-sectional area of the nozzle orifice can be in the range of 0.1 mm²-10 mm². For example, the flow rate of the powder can be in the range of 10-500 grams per minute. For example, the particle size distribution of the powder can be in the range of 10-100 μm. For example, the flow rate of the precursor gas can be in the range of 0.01-0.5 standard liters per minute. For example, the flow rate of the sheath gas can be in the range of 0.05-1 standard liters per minute.

While various examples of the flow rates are provided, it should be noted that these flow rates depend on and therefore can be selected based on various factors. The factors include but are not limited to the type of material of the powder, the particle size distribution of the powder, the flowability of the powder, the cross-sectional area of the nozzle, the process performed (i.e., building or repairing a component), the material and design of the component being built or repaired, the design of the apparatus (e.g., the size and shape of the apparatus, the length of the coil used to generate the plasma, and so on), the types of precursor and sheath gases, the type and amount (i.e., concentration) of the dopant, and so on.

Some of the flow rates can be varied during printing. Further, the flow rates of the powder and the precursor gas should be sufficient to allow atomization of the powder. The flow rate of the sheath gas should be greater than the flow rate of the precursor gas so that the sheath gas can keep the material exiting the nozzle focused and directed to the substrate. The sheath gas can also be an inert gas and can be heavier than the precursor gas (i.e., can have a greater atomic number than the precursor gas). Further, while the apparatus is shown and described as being circular in shape, the apparatus can have any other shape (e.g., rectangle, hexagon, etc.).

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

The program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system comprising:
an apparatus having a nozzle;
an element arranged around the apparatus;
a feeder configured to supply a powder of a material into the apparatus;
a gas source configured to supply a precursor gas into the apparatus and to supply an inert gas to circulate through a space between the element and the apparatus and to exit around the nozzle; and
a plasma generator arranged in the apparatus and configured to ionize the precursor gas and atomize the powder and to eject through the nozzle a jet of particles composed of the atomized powder and the ionized precursor gas onto a substrate arranged adjacent to the nozzle.

2. The system of claim 1 wherein the material is selected from a group consisting of silicon, ceramics, and refractory metals.

3. The system of claim 1 further comprising a controller configured to maintain a temperature of the substrate and materials deposited on the substrate to less than a ductile to brittle transition temperature of the material.

4. The system of claim 1 wherein the apparatus deposits one or more layers of the particles onto the substrate.

5. The system of claim 1 further comprising a controller configured to alter one or more of electrical, thermal, and chemical properties at a plurality of locations in a single layer or across a plurality of layers of the particles deposited onto the substrate by controlling one or more of the feeder, the gas source, and the plasma generator.

6. The system of claim 1 further comprising a controller configured to select a dopant to add to the material into the apparatus during deposition of one or more layers of the particles onto the substrate.

7. The system of claim 1 further comprising a controller configured to select, during deposition of one or more layers of the particles onto the substrate, at least one of:
a type of the material; and
a feed rate of the selected material supplied by the feeder.

8. The system of claim 1 further comprising a controller configured to select, during deposition of one or more layers of the particles onto the substrate, at least one of:
a type of the precursor gas; and
a flow rate of the selected precursor gas supplied by the gas source.

9. The system of claim 1 further comprising a controller configured to select power supplied to the plasma generator during deposition of one or more layers of the particles onto the substrate.

10. The system of claim 1 further comprising:
a gantry system configured to move at least one of the apparatus and the substrate; and
a controller configured to move the gantry system during deposition of one or more layers of the particles onto the substrate.

11. The system of claim 1 wherein the apparatus has a circular shape and a conical end forming the nozzle and wherein the element is arranged concentrically around the apparatus.

12. A method comprising:
supplying a powder of a material into an apparatus having a nozzle;
supplying a precursor gas into the apparatus;
generating plasma in the apparatus to ionize the precursor gas and atomize the powder;
circulating an inert gas around the apparatus to minimize interaction between the plasma and ambient atmosphere and to focus a plasma jet composed of materials including the atomized powder and the ionized precursor gas onto a substrate arranged adjacent to the nozzle of the apparatus; and
controlling a temperature of the substrate and the materials deposited on the substrate to less than a ductile to brittle transition temperature of the material.

13. The method of claim 12 further comprising selecting the material from a group consisting of silicon, ceramic, and refractory metal.

14. The method of claim 12 further comprising depositing one or more layers of the materials onto the substrate.

15. The method of claim 12 further comprising controlling one or more of electrical, thermal, and chemical properties at a plurality of locations in a single layer or across a plurality of layers of the materials deposited onto the substrate by controlling one or more of a type of the material, a rate of supplying the powder, a type of the precursor gas, and a rate of supplying the precursor gas.

16. The method of claim 12 further comprising controlling supply of a dopant into the apparatus during deposition of one or more layers of the materials onto the substrate.

17. The method of claim 12 further comprising, during deposition of one or more layers of the materials onto the substrate, at least one of:
selecting a type of the material; and
controlling a feed rate of the selected material.

18. The method of claim 12 further comprising, during deposition of one or more layers of the materials onto the substrate, at least one of:
selecting a type of the precursor gas; and
controlling a flow rate of the selected precursor gas.

19. The method of claim 12 further comprising controlling power supplied for generating the plasma during deposition of one or more layers of the materials onto the substrate.

20. The method of claim 12 further comprising moving at least one of the apparatus and the substrate during deposition of one or more layers of the materials onto the substrate.
